(19) United States
(12) Patent Application Publication
(10) Pub. No.: US 2008/0150057 A1
(43) Pub. Date: Jun. 26, 2008

(54) IMAGE SENSOR AND METHOD OF MANUFACTURING THE SAME

(75) Inventors: Yun-Ki LEE, Seoul (KR); Duck-Hyung LEE, Gyeonggi-do (KR); Chang-Rok MOON, Seoul (KR); Sung-Ho HWANG, Seoul (KR); Doo-Won KWON, Gyeonggi-do (KR); Gil-Sang YOO, Gyeonggi-do (KR); Seung-Hun SHIN, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/951,070

(22) Filed: Dec. 5, 2007

(30) Foreign Application Priority Data
Dec. 5, 2006 (KR) 10-2006-0122244

(51) Int. Cl. H01L 31/0232; H01L 31/18

(52) U.S. Cl. 257/432; 438/70; 257/E31.127

(57) ABSTRACT

An image sensor and a method of manufacturing the same are disclosed. An image sensor is formed by forming a photoelectric transformation element at a front surface of a semiconductor substrate in an active pixel sensor region and in an optical black region of the semiconductor substrate, subjecting a surface of the semiconductor substrate opposite the front surface to a removal process to create a back surface of the semiconductor substrate, and forming a light blocking film pattern on the back surface in the optical black region. The light blocking film pattern includes an organic material.

### CROSS REFERENCE TO RELATED APPLICATION

This application claims the benefit of foreign priority to Korean Patent Application No. 10-2006-0122244 filed on Dec. 5, 2006, the disclosure of which is incorporated herein by reference in its entirety.

### BACKGROUND

1. Field of Invention

Embodiments of the present invention relate generally to image sensors methods of manufacturing image sensors, and more particularly, to an image sensor capable of supplying a stable reference signal and a method of manufacturing such an image sensor.

2. Description of the Related Art

Image sensors are elements for converting optical images into electrical signals. In recent years, as a computer industry and communication industry have become more developed, demands on image sensors having improved performance characteristics have increased in various fields, such as digital cameras, camcorders, personal communication systems (PCSs), game devices, security cameras, medical micro cameras, robots, and the like.

An image sensor typically includes an active pixel sensor region and an optical black region. In the active pixel sensor region, unit pixels are arranged in a matrix. The unit pixels photoelectrically transform incident light and supply image signals. In the optical black region, unit pixels shielded from incident light are arranged adjacent to the active pixel sensor region. The unit pixels shielded from incident light supply a constant reference signal, regardless of incident light. Accordingly, the optical black region prevents the levels of the image signals from changing due to temperature difference. That is, it is regarded that a voltage level of the reference signal is affected by ambient temperature. For this reason, signals generated by the incident light are calculated using the voltage difference between the image signal and the reference signal.

Accordingly, the optical black region is covered with a metal light blocking film so as to supply a stable reference signal to the incident light. The metal light blocking film is formed using a general etching process. As a result of the etching process, a surface of a semiconductor substrate on which the unit pixels are formed may become damaged, thereby creating charge traps due to dangling silicon bonds at the surface of the semiconductor substrate. For this reason, the image sensor may generate a signal indicating that light is being irradiated even though no light is actually being irradiated. This effect is known as the “dark current” effect. As a result, the image sensor may generate distorted signals. When the distorted signals are generated, a difference in the voltage level between the image signal and the reference signal becomes smaller as compared to when normal (i.e., undistorted) reference signals are generated. Accordingly, the image quality of the image sensor can deteriorate significantly.

### SUMMARY

One embodiment of the present invention can be characterized as providing a method of manufacturing an image sensor that can supply a stable reference signal. Another embodiment of the present invention can be characterized as providing an image sensor capable of supplying a stable reference signal.

One exemplary embodiment of the present invention can be generally characterized as a method of manufacturing an image sensor that includes providing a semiconductor substrate having an active pixel sensor region and an optical black region; forming a photoelectric transformation element at a front surface of the semiconductor substrate in the active pixel sensor region and forming a photoelectric transformation element at the front surface of the semiconductor substrate in the optical black region; subjecting a surface of the semiconductor substrate opposite the front surface to a removal process to create a back surface; and forming a light blocking film pattern on the back surface in the optical black region, wherein the light blocking film pattern includes an organic material.

Another exemplary embodiment of the present invention can be generally characterized as an image sensor that includes a semiconductor substrate having an active pixel sensor region and an optical black region; a photoelectric transformation element at a front surface of the semiconductor substrate in the active pixel sensor region and a photoelectric transformation element at the front surface of the semiconductor substrate in the optical black region; a light blocking film pattern on a back surface of the semiconductor substrate opposite the front surface in the optical black region, wherein the back surface of the semiconductor substrate is created by subjecting a surface of the semiconductor substrate opposite the front surface to a removal process and wherein the light blocking film pattern comprises an organic material.

### BRIEF DESCRIPTION OF THE DRAWINGS

The above and other features of the embodiments of the present invention will become more apparent with reference to the attached drawings in which:

FIG. 1 is a view showing a pixel array of an image sensor according to one embodiment;

FIG. 2 is a conceptual diagram illustrating the operation of the pixel array of the image sensor according to one embodiment;

FIG. 3 is a circuit diagram of a unit pixel of the image sensor according to one embodiment;

FIGS. 4 to 9 are cross-sectional views illustrating an exemplary method of manufacturing an image sensor according to one embodiment; and

FIG. 10 is a view schematically showing a configuration of a processor-based system that includes a CMOS image sensor according to one embodiment.

### DETAILED DESCRIPTION

Features of embodiments of the present invention, and methods of accomplishing the same, may be understood more readily by reference to the following detailed description and the accompanying drawings. Embodiments of the present invention may, however, be realized in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the embodiments described herein, a detailed description of known device structures and techniques incorporated herein will be omitted when it may make the subject matter of the present invention unclear. In addition, n-type or p-type is only an example, and each embodiment described and exemplified in this specification includes complementary embodiments thereof. Like reference numerals refer to like elements throughout the specification.

As used herein, the term “and/or” includes any and all combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terminology used herein is for the purpose of describing particular embodiments only and is not intended to be limiting of the invention.

An image sensor according to embodiments exemplarily described herein includes a CCD (Charge Coupled Device) and a CMOS image sensor. The CCD has less noise and higher image quality as compared to the CMOS image sensor. However, the CCD requires a relatively high voltage and a process cost of the CCD is also relatively high. It is relatively easy to drive CMOS image sensors, and various scanning methods can be applied to the CMOS image sensor. Further, signal-processing circuits and a CMOS image sensor can be integrated into a single chip to reduce the size of an end-product. Furthermore, because CMOS process technologies are compatible, it is possible to reduce manufacturing cost of the CMOS image sensor. In addition, because the power consumption of the CMOS image sensor is very small, it is possible to easily apply the CMOS image sensor to devices that are limited by battery capacities. For this reason, the CMOS image sensor will be exemplified below as the image sensor of the present invention. However, the scope and spirit of the present invention may be applied to the CCD.

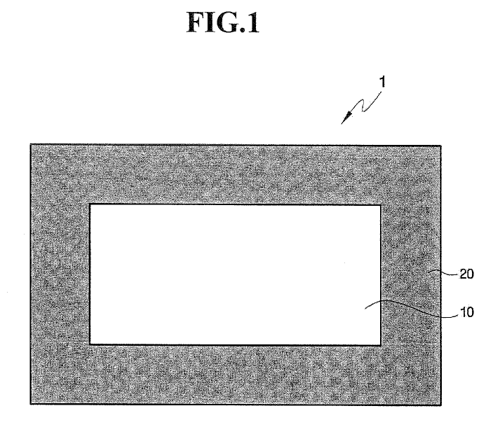

Referring to FIGS. 1 to 10, it is possible to easily understand an image sensor according to various embodiments of the present invention.

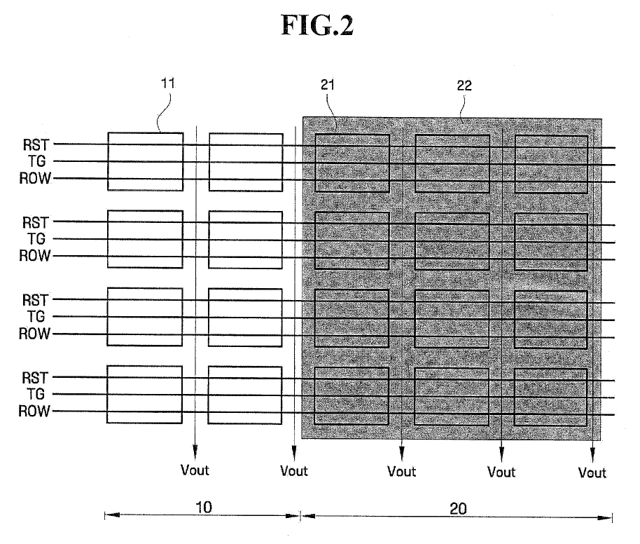

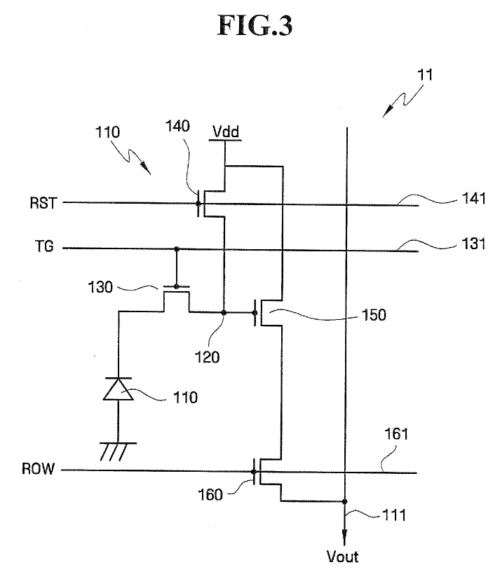

FIG. 1 is a view showing a pixel array of an image sensor according to one embodiment. FIG. 2 is a conceptual diagram illustrating the operation of the pixel array of the image sensor shown in FIG. 1. FIG. 3 is a circuit diagram of a unit pixel of the image sensor shown in FIG. 1.

Referring to FIGS. 1 and 2, a pixel array 1 of an image sensor according to one embodiment may generally include an active pixel sensor region 10 and an optical black region 20.

Unit pixels 11 photoelectrically transform incident light to provide image signals (Vout). The unit pixels 11 may be arranged in a matrix in the active pixel sensor region 10, as shown in FIG. 2. The unit pixels 11 are driven upon receiving a plurality of driving signals (e.g., pixel selection signals ROW, reset signals RST, charge transfer signals TG, etc.) from a row driver (not shown).

As shown in FIG. 3, each of the unit pixels 11 may, for example, include a photoelectric transformation element 110, a charge detection element 120, a charge transfer element 130, a reset element 140, an amplifying element 150, and a selection element 160. In the embodiment illustrated in FIG. 3, each of the unit pixels 11 includes four transistor structures. It will be appreciated, however, that each of the unit pixels 11 may include less (e.g., three) or more (e.g., five) than four transistor structures.

The photoelectric transformation element 110 absorbs incident light, and accumulates charges corresponding to the amount of the light. The photoelectric transformation element 110 may, for example, include a photo diode, a photo transistor, a photo gate, a pinned photo diode (PPD), or the like or a combination thereof.

The charge detection element 120 may, for example, include a floating diffusion region (FD). Charges accumulated by the photoelectric transformation element 110 are transferred to the charge detection element 120. Because the charge detection element 120 has a parasitic capacitance, charges may be accumulated therein. Because the charge detection element 120 is electrically connected to a gate of the amplifying element 150, the charge detection element 120 may control the amplifying element 150.

The charge transfer element 130 transfers charges from the photoelectric transformation element 110 to the charge detection element 120. The charge transfer element 130 may include, for example, one transistor and be controlled by a charge transfer signal TG.

The reset element 140 may periodically reset the charge detection element 120. A source of the reset element 140 is connected to the charge detection element 120 and a drain thereof is connected to a Vdd. Further, the reset element 140 may be driven in response to a reset signal RST.

The amplifying element 150 and a constant current source (not shown, which may be disposed outside the unit pixel 11), serve as a source follower buffer amplifier. A voltage changed in response to a voltage of the charge detection element 120 is output to a vertical signal line 111. A source of the amplifying element 150 is connected to a drain of the selection element 160, and a drain thereof is connected to the Vdd.

The selection element 160 may select unit pixels 11 to be read in a row and may be driven in response to a selection signal ROW. A source of the selection element 160 is connected to the vertical signal line 111.

Further, driving signal lines 131, 141 and 161 of the charge transfer element 130, the reset element 140, and the selection element 160, respectively, may extend along a row direction (e.g., a horizontal direction) so that the unit pixels 11 in the same row of the matrix are driven at the same time.

Referring to FIGS. 1 and 2, the optical black region 20 is formed adjacent to the active pixel sensor region 10. Unit pixels 21 (hereinafter referred to as “reference pixels”) are arranged in the optical black region 20 and are shielded from incident light. The optical black region 20 may surround the active pixel sensor region 10. In one embodiment, each of the reference pixels 21 may have substantially the same structure as the above-mentioned unit pixel 11 in the active pixel sensor region 10. However, a light blocking film 22 made of an organic material that is substantially opaque to incident light may be formed on the photoelectric transformation elements. As a result, substantially no light is irradiated on the photoelectric transformation elements of the reference pixels 21.

Even though incident light is irradiated on the optical black region 20, the light blocking film 22 substantially prevents the incident light from being irradiated on the reference pixels 21. Accordingly, even though incident light reflected from a specific object is irradiated on the unit pixels 11, charges caused by the incident light are not generated by the reference pixels 21, which are shielded from the incident light. As a result, while the incident light irradiated on the unit pixels 11 is converted into electrical signals, the reference pixels 21, shielded from incident light, provide an electrical signal. In one embodiment, electrical signals provided by the reference pixels 21 may be used to generate a reference signal. In one embodiment, the reference signal may be an average of electrical signals output from the reference pixels 21, to ensure the accuracy thereof.

Using the reference pixels 21 in the optical black region 20, a reference signal is generated with respect to the evaluation of an element. That is, the reference signal is used to measure a degree of blooming, smear, or charge transfer efficiency (CTE). Accurate evaluation of the reference signal is advantageously used to quantitatively evaluate the signal level, and is required to obtain accurate images. Accordingly, it is necessary to accurately and stably measure reference signals. Light is maximally blocked in the optical black region so that noise caused by light transmission can be maximally suppressed. As a result, it is possible to achieve a substantially stable reference signal.

According to one embodiment, a light blocking film made of a light-blocking organic material such as black matrix may be used to block incident light in the optical black region 20. The light blocking film 22 may be formed on a substrate at a location substantially corresponding to a location of the optical black region 20. Because a light blocking film 22 is made of an organic material instead of metal, as in the related art, defects caused by damage to the semiconductor substrate during a process of etching the metal light blocking film can be avoided.

Moreover, and as described above, charge traps generated during a metal etching process may cause the image sensor to generate a signal indicating that light is being irradiated even though no light is actually being irradiated. However, according to embodiments described herein, the light blocking film 22 includes light-blocking organic material that can be selectively removed simply by exposure and development processes. Accordingly, the surface of the substrate can be prevented from being damaged due to etching processes. Further, the physical etch stress caused by an etching process can be reduced to simplify the process. In addition, when a metal (e.g., aluminum) light blocking film is used, a passivation film (e.g., a nitride film or an oxide film) should be formed on the light blocking film to prevent the aluminum film from deteriorating due to moisture. However, when the light blocking film according to embodiments of the present invention is used, the above-mentioned passivation film may be omitted. As a result, a height difference between the light blocking film and a subsequently formed color filter can be reduced.

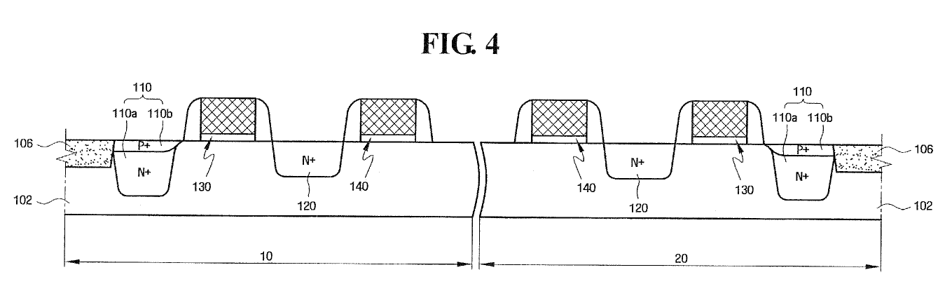

A method of manufacturing an image sensor according to one embodiment will be described with reference to FIGS. 4 to 9.

The CMOS image sensor in the related art has a structure in which light is irradiated from a lens formed on multiple wiring layers to a photoelectric transformation element through gaps between the wiring layers and then detected. The amount of incident light actually irradiated on the photoelectric transformation element is insufficient due to the multiple wiring layers. For example, because the opening ratio in respect to the photoelectric transformation element is reduced due to the layout including the multiple wiring layers, the amount of incident light actually irradiated on the photoelectric transformation element is significantly reduced. For this reason, the sensitivity of the CMOS image sensor may deteriorate. Thus, in accordance with one embodiment, the image sensor manufactured according to the exemplary method shown in FIGS. 4 to 9 may be provided as a back-illuminated image sensor including a microlens formed on the back of a semiconductor substrate 102. The back-illuminated image sensor has the structure in which light is irradiated from the back side (a side opposite to a wiring part) of the semiconductor substrate 102 and received by the photoelectric transformation element. Accordingly, it is possible to improve an effective opening ratio, regardless of the layout including the multiple wiring layers, and to significantly improve the sensitivity of the CMOS image sensor.

Referring to FIG. 4, an image sensor may, for example, include element isolation regions 106 formed in a front surface of the semiconductor substrate 102 in the active pixel sensor region 10 and the optical black region 20.

The semiconductor substrate 102 may, for example, include a P-type substrate. Although not shown, a P-type epitaxial layer or separate well region may be formed on the semiconductor substrate 102. Next, the photoelectric transformation element 110, the charge transfer element 130, and the reset element 140 may be formed on semiconductor substrate 102 (or on the P-type epitaxial layer and/or the well region).

Each of the element isolation regions 106 may define an active pixel sensor region 10 on the semiconductor substrate 102 and may, for example, include FOX (Field OXide) or STI (Shallow Trench Isolation) that is formed by, for example, a LOCOS (LOCal Oxidation of Silicon) method, or the like. In one embodiment, the element isolation regions 106 may be formed by forming trenches in the active pixel sensor region 10 and the optical black region 20 and filling the trenches with an insulating material. In such an embodiment, the insulating material may, for example, include an oxide film. The depth of each trench may be in the range of, for example, about 400 Å to 500 Å.

A plurality of unit pixels 11 are arranged at the front surface of the semiconductor substrate 102 in the active pixel region 10 and a plurality of reference pixels 21 are arranged at the front surface of the semiconductor substrate 102 in the optical black region 20. As mentioned above, each of the unit pixels 11 and the reference pixels 21 may include the aforementioned photoelectric transformation element 110, the charge detection element 120, the charge transfer element 130, the reset element 140, the amplifying element 150, the selection element 160 and the like. In one embodiment, the photoelectric transformation element 110 may be provided as a pinned photo diode (PPD). It will be appreciated, however, that the photoelectric transformation element 110 may also be provided as a photo diode, a photo transistor, a photo gate, or the like or a combination thereof.

The photoelectric transformation element 110 accumulates charges generated upon absorbing energy of incident light, and may include an N⁺-type photo diode 110a and a P⁺-type pinning layer 110b. In one embodiment, the photo diode and the pinning layer may be formed by two different ion-implantation processes.

According to the image sensor of the related art, surface damage of the photo diode-type photoelectric transformation elements 110 may be a cause of the dark current effect. The surface damage may be caused by dangling silicon bonds as well as be caused by defects relating to the etch stress in the process of manufacturing gates, spacers, and the like. Thus, according to one embodiment of the present invention, the photoelectric transformation element 110 may be formed by forming a photo diode 110a at the front surface of the semiconductor substrate 102 followed by forming the pinning layer 110b at the front surface of the semiconductor substrate 102. As a result, it is possible to prevent the dark current from being generated so that charges generated by the energy of incident light can be easily transferred.

The charges accumulated by the photoelectric transformation element 110 are transferred to the charge detection element 120 through the charge transfer element 130 and the charge detection element 120 is formed according to an implantation of N⁺ dopant.

The charge transfer element 130 may include a transistor (i.e., a switching element) and may, for example, include a gate insulating film, a gate electrode, and a spacer.

The reset element 140 may include a transistor (i.e., a switching element) and may, for example, include a gate insulating film, a gate electrode, and a spacer.

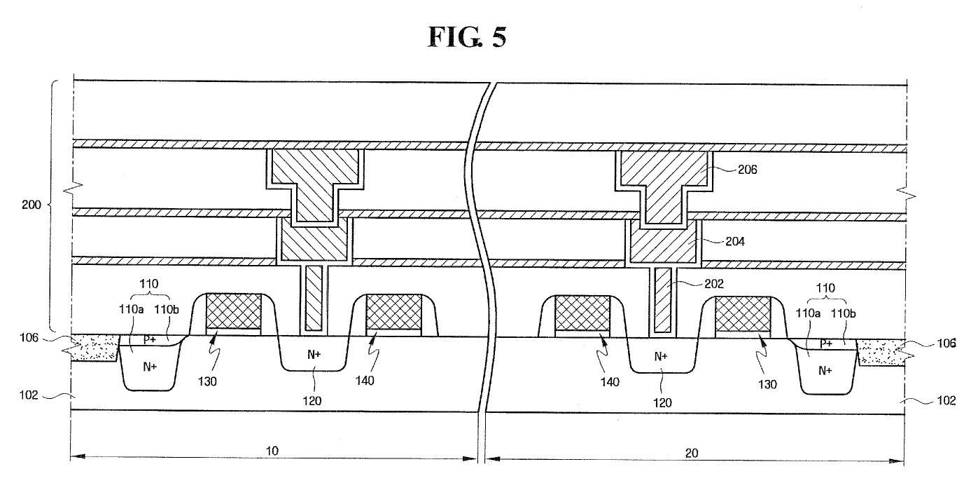

Referring to FIG. 5, an interlayer insulating film 200 may be formed on structure shown in FIG. 4. Accordingly, the interlayer insulating film 200 may be formed on a structure in which the plurality of unit pixels 11 and the reference pixels 21 are formed.

In one embodiment, the interlayer insulating film 200 may include a plurality of wiring layers. In another embodiment, the interlayer insulating film 200 may further include contacts 202 and/or wires 204 and 206 that extend through the multiple wiring layers.

The contacts and wires may, for example, include a conductive material such as metal (e.g., copper, aluminum, or the like or a combination thereof). The wires 204 and 206 may be used to transmit predetermined signals. Although FIG. 5 illustrates wires 206 as damascene structures, it will be appreciated that the structure of the wires 206 is not limited thereto. Rather, the structure of the wires 206 and 204 may be modified depending on the configuration of the image sensor.

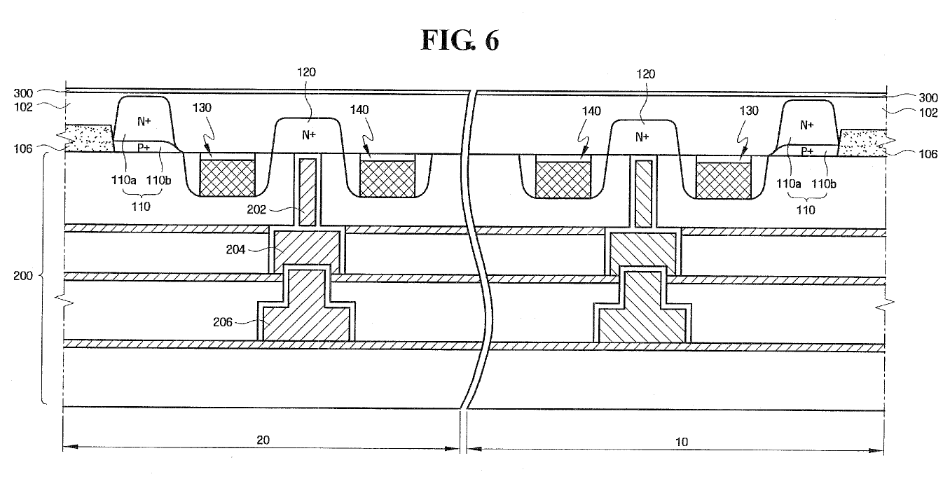

Referring to FIG. 6, a surface of the semiconductor substrate 102 opposite the front surface may be subjected to a removal process to produce a back surface of the semiconductor substrate 102 having a substantially uneven surface topography. In one embodiment, the removal process may include a grinding or polishing process performed, for example, by turning the semiconductor substrate 102 upside down (e.g., such that the front surface of the semiconductor substrate 102 faces downward) followed by performing a grinding process to reduce the thickness of the semiconductor substrate 102 by a predetermined amount. In one embodiment, the grinding of the semiconductor substrate 102 may be performed using a CMP process. In this way, contaminants may be removed from the back of the semiconductor substrate 102 and the thickness of the semiconductor substrate 102 adjacent to the photoelectric transformation element 110 is reduced. By performing the grinding, the sensitivity of the photoelectric transformation element 110 to incident light may be improved.

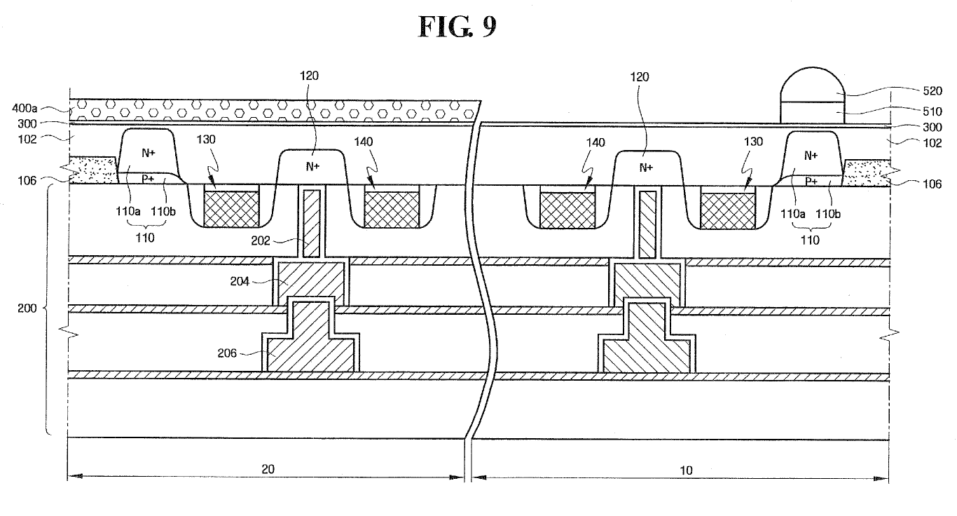

Next, a planarization film 300 may be formed. The planarization film 300 may create a substantially planarized surface topography on the back surface of the semiconductor substrate 102 before a light blocking film is formed in the optical black region 20. The back surface of the semiconductor substrate 102 has a “substantially uneven surface topography” to the extent that, if a color filter 510 (see FIG. 9) were formed so as to directly contact the back surface of the semiconductor substrate 102, the color filter 510 would be undesirably deformed. Accordingly, the planarization film 300 may provide a substantially planarized surface topography on the back surface of the semiconductor substrate 102 to prevent the subsequently formed color filter 510 from becoming undesirably deformed. In one embodiment, the planarization film 300 may, for example, include an anti-reflective layer (ARL).

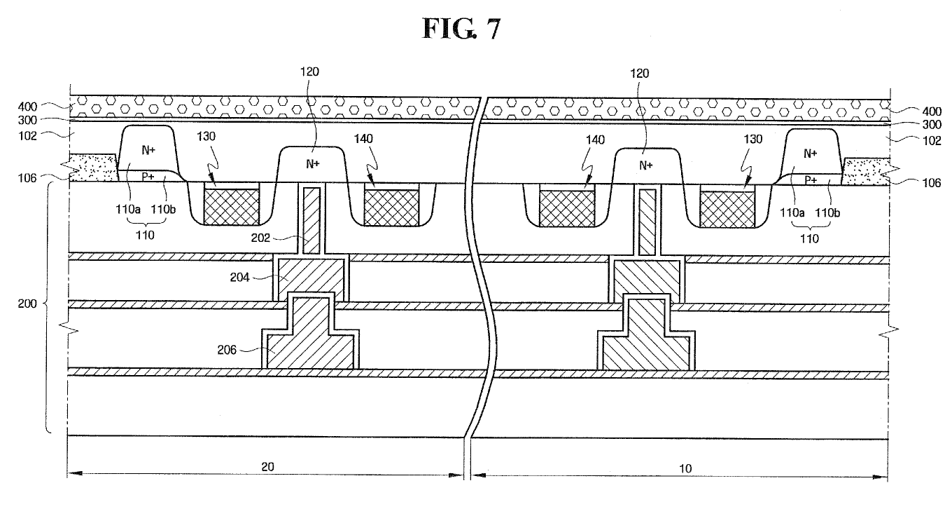

Referring to FIG. 7, a light blocking film 400 made of a light-blocking organic material may be formed in the optical black region 20. In one embodiment, a light-blocking organic material may be applied across the entire back surface of the semiconductor substrate 102.

In one embodiment, the light-blocking organic material includes a light-blocking organic material such as black matrix, carbon black, or the like or a combination thereof. For example, the light-blocking organic material may be an organic material that includes carbon black, which transmits light in the ultraviolet band but substantially blocks light in the visible light band.

In one embodiment, the light blocking film 400 may be formed using a spin coating method. The thickness of the light blocking film 400 may be in the range of about 4000 Å to about 1 μm. It will be appreciated, however, that the thickness of the light blocking film 400 is not limited thereto. Rather, the thickness of the light blocking film may be reduced depending on the processes. The light transmittance of the light blocking film 400 may be in the range of about 0.001 to about 0.01%. For example, when the thickness of the light blocking film 400 is about 1 μm, the light transmittance of the light blocking film 400 may be about 0.003%.

It is possible to determine an optical density of the light blocking film using the light transmittance of the light blocking film 400. As used herein, the term “optical density” refers to the intensity of light having a predetermined wavelength that is transmitted through a material layer. The optical density of the light blocking film 400 can be obtained by dividing the transmittance light blocking film 400 by the thickness of the light blocking film 400, and converting the resultant value. Accordingly, a light blocking film 400 having a transmittance of about 0.003% at a thickness of about 1 μm can be determined to have an optical density of about 3.5. The ability of the light blocking film 400 to substantially block light increases as the optical density of the light blocking film 400 increases. Accordingly, if the thickness of the light blocking film 400 is reduced, the optical density may be increased to about 3.5 or more. Therefore, it is possible to effectively block light by adjusting the thickness of the light blocking film 400.

The light blocking film 400 may be formed according to process that is relatively simple as compared to a process necessary to form conventional metal light blocking films. For example, a conventional metal light blocking film may be formed by etching a metal film followed by forming a passivation film on the etched metal film. By removing at least these steps required to form a metal light blocking film, it is possible to improve the efficiency with which the image sensor is manufactured.

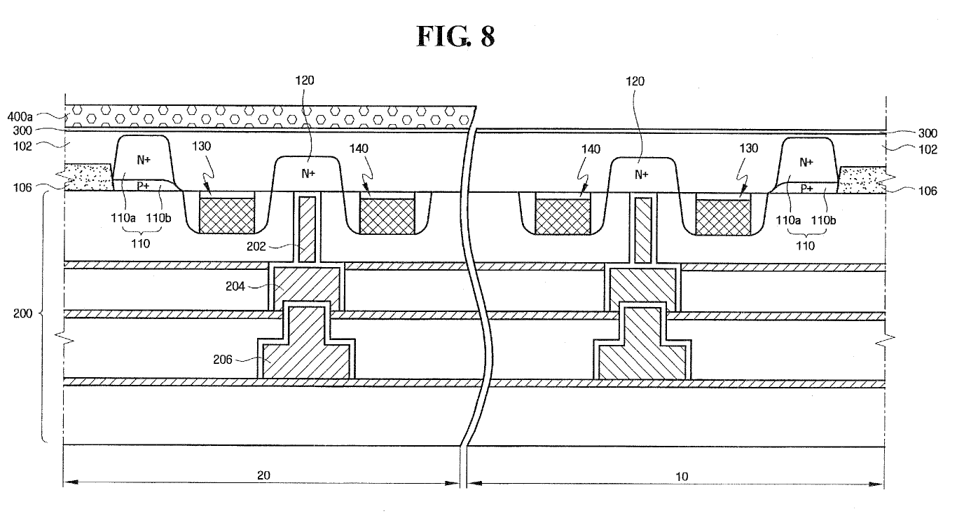

Next, referring to FIG. 8, a portion of the light blocking film 400 formed on the back surface of the semiconductor substrate 102 at a location substantially corresponding to the location of the active pixel sensor region 10 may be removed. In one embodiment, the light blocking film 400 may be removed by performing exposure and development processes. For example, and as mentioned above, the light blocking film 400 can effectively transmit light in the ultraviolet band. Accordingly, an exposure process can be performed in which the light blocking film 400 is exposed to light in the ultraviolet band. After the exposure process, a developing process is performed in which the light blocking film 400 is developed using a developer. Accordingly, it is possible to easily and selectively remove only the portion of the light blocking film 400 at a location substantially corresponding to the location of the active pixel sensor region 10.

Upon patterning the light blocking film 400, a light blocking film pattern 400a remains only on the back surface of the semiconductor substrate 102 at a location substantially corresponding to a location of the optical black region 20. Next, a hard bake may be performed to harden the light blocking film pattern 400a. In one embodiment, the hard bake may be performed at a temperature in the range of about 200° C. to about 250° C. During the hard bake, solvents within the light blocking film pattern 400a are volatilized or vaporized (i.e., thermally desorbed). Upon vaporization of the solvents, the light blocking film pattern 400a becomes hardened to substantially block light. In addition, the light blocking film pattern can be protected from external physical stress.

Next, referring to FIG. 9, a color filter 510 and a microlens 520 may be formed at a location substantially corresponding to a location of the photoelectric transformation element 110 on the back surface of the semiconductor substrate 102 in the active pixel sensor region 10. The color filter 510 may be formed on the planarization film 300 at a location substantially corresponding to a location of the photoelectric transformation element 110 in the active pixel sensor region 10.

In one embodiment, the color filter 510 may be formed by applying a material layer on the planarization film 300 and then patterning the material layer using an appropriate mask. In one embodiment, the material layer may include dyed photoresist material. In one embodiment, the color filter 510 may be a red, green or blue color filter. In another embodiment, the color filter 510 may be a yellow, magenta or cyan color filter.

In one embodiment, the color filter 510 may be formed to have substantially the same thickness as the light blocking film pattern 400a. In one embodiment, the thickness of the color filter 510 may be controlled by controlling the viscosity of the dyed photoresist material used to form the color filter 510 and by controlling the revolutions per minute (RPM) of a spin coating process used to apply the dyed photoresist material on the planarization film 300. For example, when the viscosity of the dyed photoresist material is controlled to be relatively low, the thickness of the color filter 510 can be controlled by setting the RPM in the spin coating process to a predetermined value. When the viscosity of the dyed photoresist material is relatively high, the thickness of the color filter 510 can be controlled by decreasing the RPM in the spin coating process relative to the predetermined value.

As described above, the color filter 510 may be formed to have substantially the same thickness as the light blocking film pattern 400a. When a conventional metal light blocking film is formed, a passivation film must also be formed to prevent deterioration of the metal light blocking film caused by moisture. However, when dyed photoresist material is applied on a resultant structure to form the color filter 510, a large height difference occurs between the passivation film and the upper surface of the substrate corresponding to the active pixel sensor region 10. As a result, a photoresist-lifting (PR lifting) phenomenon may occur. However, because a separate passivation film is not formed on the light blocking film pattern 400a exemplarily described above, it is possible to reduce the height difference. Further, because the color filter 510 may be formed to have substantially the same thickness as that of the light blocking film pattern 400a, it is possible to substantially eliminate the height difference.

The microlens 520 may be formed on the color filter 510 in the active pixel sensor region 10. In one embodiment, the microlens 520 may include a material such as a photoresist having high transmittance. The microlens 520 may be formed to be aligned at a location substantially corresponding to a location of the photoelectric transformation element 110. In one embodiment, the microlens 520 may be formed by applying a high-transmittance photoresist material over the color filter 510 and patterning the applied photoresist to be aligned at a location substantially corresponding to a location of the photoelectric transformation element 110. Subsequently, a reflow process may be performed using a thermal process so form a microlens 520 having a hemispherical shape (i.e., a dome shape). Although not shown in the drawings, an overcoating layer may be provided between the color filter 510 and the microlens 520.

The microlens 520 is formed on the back surface of the semiconductor substrate 102. As a result, it is possible to form a back-illuminated image sensor having the structure in which light is irradiated onto the back side of the semiconductor substrate 102 and received by the photoelectric transformation element 110 used as a light receiving part.

As exemplarily described herein, a back-illuminated image sensor is provided to prevent the opening ratio in respect to the photoelectric transformation element 110 from being reduced due to a layout including multiple wiring layers. Further, because a light blocking film made of a light-blocking organic material is formed in the optical black region 20, it is possible to form the light blocking film pattern 400a simply (e.g., by exposure and development processes). In addition, by providing the light blocking film pattern 400a, it is possible to reduce physical stresses that would otherwise be caused by etching processes. Accordingly, it is possible to obtain an image sensor capable of supplying a stable reference signal.

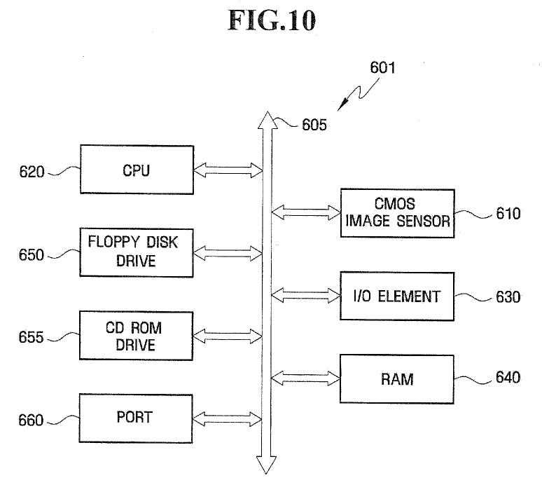

FIG. 10 is a schematic view showing the configuration of a processor-based system that includes a CIS according to one embodiment.

Referring to FIG. 10, a processor-based system 601 may be a system for processing images that are output from a CMOS image sensor (CIS) 610. The processor-based system 601 may, for example, include a computer system, a camera system, a scanner, a mechanized watch system, a navigation system, a videophone, a master system, an autofocus system, a tracking system, a motion monitoring system, an image stabilization system, or the like or a combination thereof. It will be appreciated, however, that the processor-based system 601 is not limited thereto.

In some embodiments, the processor-based system 601 may include a central processing unit (CPU) 620 (e.g., a microprocessor) that can communicate with an I/O element 630 through buses 605. The CIS 610 may communicate with the system through the buses 605 or other communication links. Further, the processor-based system 601 may further include a RAM 640, a floppy disk drive 650 and/or a CD ROM drive 655, and a port 660 that communicates with the CPU 620 through the buses 605. The port 660 may be used to couple a video card, a sound card, a memory card, and a USB element, or the like, or a combination thereof, with each other. Alternatively, the port 660 may be used to transmit data to another system. The CIS 610 may be integrated together with the CPU, a digital signal processor (DSP), a microprocessor, or the like, or a combination thereof. Alternatively, the CIS 610 may be integrated together with a memory. In some cases, the CIS 610 may be integrated into a chip separated from the processor.

Although embodiments of the present invention have been described above, it will be apparent to those skilled in the art that various modifications and changes may be made thereto without departing from the scope and spirit of the invention. Therefore, it should be understood that the above embodiments are not limitative, but illustrative in all respects.

The exemplary method of manufacturing an image sensor, and the image sensor exemplarily described above, may be advantageous in at least the following respects. First, because a light blocking film made of a light-blocking organic material is formed in an optical black region, it is unnecessary to perform an etching process and a passivation film forming process for a light blocking film. Second, because a light blocking film is made of an organic material, it is possible to form the light blocking film simply (e.g., by exposure and development processes). Third, because an etching process for a light blocking film is not performed, it is possible to prevent the surface of a substrate from being damaged. Fourth, because it is possible to prevent the surface of a substrate from being damaged, it is also possible to obtain an image sensor capable of supplying a stable reference signal.

What is claimed is:

1. A method of manufacturing an image sensor, the method comprising:
providing a semiconductor substrate having an active pixel sensor region and an optical black region;
forming a photoelectric transformation element at a front surface of the semiconductor substrate in the active pixel sensor region and forming a photoelectric transformation element at the front surface of the semiconductor substrate in the optical black region;
subjecting a surface of the semiconductor substrate opposite the front surface to a removal process to create a back surface of the semiconductor substrate opposite the front surface; and
forming a light blocking film pattern on the back surface in the optical black region, wherein the light blocking film pattern comprises an organic material.

2. The method of claim 1, wherein forming the light blocking film pattern comprises:
forming a light blocking film on the back surface of the semiconductor substrate; and
removing a portion of the light blocking film located on the back surface of the semiconductor substrate in the active pixel sensor region.

3. The method of claim 2, wherein forming of the light blocking film is performed using a spin coating method.

4. The method of claim 2, further comprising performing a hard bake to harden the light blocking film after removing the portion of the light blocking film.

5. The method of claim 1, wherein the organic material comprises carbon black.

6. The method of claim 1, wherein the light blocking film pattern has a thickness of about 4000 Å to about 1 μm.

7. The method of claim 1, wherein light blocking film pattern has a transmittance of about 0.001 to about 0.01%.

8. The method of claim 1, wherein the light blocking film pattern has an optical density of at least about 3.5.

9. The method of claim 1, further comprising forming an anti-reflective layer on the back surface of the semiconductor substrate before forming the light blocking film.

10. The method of claim 1, further comprising forming a color filter on the back surface of the semiconductor substrate at a location substantially corresponding to a location of the photoelectric transformation element at the front surface of the semiconductor substrate in the active pixel sensor region.

11. The method of claim 10, wherein the color filter is formed to have substantially the same thickness as a thickness of the light blocking film pattern.

12. The method of claim 10, further comprising forming a microlens on the color filter.

13. An image sensor comprising:
a semiconductor substrate having an active pixel sensor region and an optical black region;
a photoelectric transformation element at a front surface of the semiconductor substrate in the active pixel sensor region and a photoelectric transformation element at the front surface of the semiconductor substrate in the optical black region;
a light blocking film pattern on a back surface of the semiconductor substrate opposite the front surface in the optical black region, wherein the back surface of the semiconductor substrate is created by subjecting a surface of the semiconductor substrate opposite the front surface to a removal process and wherein the light blocking film pattern comprises an organic material.

14. The image sensor of claim 13, wherein the light blocking film pattern comprises carbon black.

15. The image sensor of claim 13, wherein the light blocking film pattern has a thickness of about 4000 Å to about 1 μm.

16. The image sensor of claim 13, wherein light blocking film pattern has a transmittance of about 0.001 to about 0.01%.

17. The image sensor of claim 13, wherein the light blocking film pattern has an optical density of at least about 3.5.

18. The image sensor of claim 13, further comprising an anti-reflective layer located between the light blocking film and the back surface of the semiconductor substrate.

19. The image sensor of claim 13, further comprising a color filter on the back surface of the semiconductor substrate at a location substantially corresponding to a location of the photoelectric transformation element at the front surface of the semiconductor substrate in the active pixel sensor region.

20. The image sensor of claim 19, wherein the color filter has substantially the same thickness as a thickness of the light blocking film pattern.

21. The image sensor of claim 19, further comprising a microlens on the color filter.
